(19) United States
(12) Patent Application Publication
(10) Pub. No.: US 2026/0135529 A1
(43) Pub. Date: May 14, 2026

(54) VOLTAGE MONITORING OF DRIVER CIRCUITS

(71) Applicant: Cirrus Logic International Semiconductor Ltd., Edinburgh (GB)

(72) Inventors: Zheng YAN, Austin, TX (US); Miles K. ROBERTO, Austin, TX (US); Roberto NAPOLI, Milan (IT); Tian ZHAO, Austin, TX (US)

(73) Assignee: Cirrus Logic International Semiconductor Ltd., Edinburgh (GB)

(21) Appl. No.: 18/945,914

(22) Filed: Nov. 13, 2024

(51) Int. Cl. H03F 3/217; H03G 3/30; H04R 3/00

(52) U.S. Cl. CPC H03F 3/2173; H03G 3/3005; H04R 3/007; H03F 2200/03; H03F 2200/426; H03F 2200/462; H03F 2200/471

(57) ABSTRACT

This application relates to methods and apparatus for monitoring the output voltage of a driver or amplifier for driving a load. A driver circuit includes a digital signal processor, which is configured to receive an input signal and output a processor output signal based on the input signal, and a switching driver which is configured to receive the processor output signal and to generate a corresponding drive signal for driving the load. The signal processor is configured to implement an estimator to generate an estimate of a voltage of the drive signal based on the processor output signal. The estimator may generate the estimate of the voltage by applying a first transfer function to the processor output signal. The first transfer function may be determined as part of a system identification process for the driver circuit.

### TECHNICAL FIELD

The field of representative embodiments of this disclosure relates to methods, apparatus and/or implementations concerning or relating to output voltage monitoring for driver circuits, and in particular to monitoring output voltages for driver circuits as may be used to drive a transducer.

### BACKGROUND

Many electronic devices include transducer driver circuitry for driving a transducer with a suitable driving signal, for instance for driving an audio output transducer of the host device or a connected accessory, with an audio driving signal.

In some applications, the driver circuitry may include a switching driver, e.g. a class-D amplifier output stage or the like, for generating the driving signal. Switching drivers, sometimes referred to as switched-mode drivers or switched-mode amplifiers, can be relatively power efficient and thus can be advantageously used in some applications. A switching driver generally operates to switch an output node between different switching voltages, with a duty cycle that provides a desired average output voltage, over the course of one or more switching cycles, for the drive signal.

In general, it may be desirable to be able to monitor the output voltage of the switching driver for various reasons, e.g. for detecting and/or avoiding signal clipping or otherwise controlling operation of the switching driver and/or for protection of the transducer.

Typically, the output voltage of a driver or amplifier may be monitored by a voltage monitor comprising a suitable analog front end (AFE) and analog-to-digital converter (ADC). Such an arrangement can, in many implementations, provide suitable monitoring of the output voltage, although generally this monitoring circuitry may require some trimming to account for process variations during manufacture, which requires testing and calibration time following manufacture. In addition, the AFE and ADC can be relatively large in terms of circuit area and, in general, there is a trend to smaller circuit footprints, where possible, for size and cost reasons. The power requirements for the AFE and ADC also impact on the power efficiency of the driver circuit.

### SUMMARY

Embodiments of the present disclosure relate to methods and apparatus for voltage monitoring in switching drivers that at least mitigate at least some of the above-mentioned issues.

According to an aspect of the disclosure there is provided a driver circuit for driving a load comprising: a digital signal processor configured to receive an input signal and output a processor output signal based on the input signal; and a switching driver configured to receive the processor output signal and to generate a corresponding drive signal for driving the load. The signal processor is configured to implement an estimator to generate an estimate of a voltage of the drive signal based on the processor output signal.

In some implementations, the switching driver may comprise an upsampler to provide upsampling of the processor output signal and the estimator may be configured to generate the estimate of the voltage of the drive signal based on the processor output signal.

The estimator may be configured to generate the estimate of the voltage of the drive signal by applying a first transfer function to the processor output signal. The first transfer function may be a stored transfer function determined as part of a system identification process for the driver circuit. The estimator may be configured to receive an indication of any gain applied by the switching driver and to scale the estimate of the voltage of the drive signal generated applying the first transfer function to the processor output signal so as to account for said gain.

The estimator may be configured to limit to maximum magnitude of the estimate of the voltage of the drive signal to a clipping threshold indicative of a maximum voltage magnitude of the driver signal that can be output from the switching driver. In some examples, the estimator may be configured to receive an indication of at least one parameter of operation of the switching driver and to determine the clipping threshold. The at least parameter of operation of the switching driver may comprise an indication of a switching voltage of the switching driver and a resistance of the load.

The driver circuit may further comprise current sensing circuitry configured to monitor an output current of the switching driver and generate a current sense signal. The digital signal processor may be configured to apply signal conditioning to the input signal to generate the processor output signal, wherein the signal conditioning uses the estimate of the voltage of the drive signal and the current sense signal to apply protection to prevent thermal overload of the load. The digital signal processor may be configured to use the estimate of the voltage of the drive signal and the current sense signal to generate a value indicative of load resistance. The estimator may be configured to receive an indication of a die temperature of the driver circuit and may be configured to apply a temperature dependent compensation to at least one of the estimate of the voltage of the drive signal and the current sense signal before generating the value indicative of load resistance. The estimator may be configured to apply calibration to the current sense signal based on the estimate of the voltage of the drive signal.

The driver circuit may be an audio driver circuit configured to drive an audio output transducer. The driver circuit may be configured to drive the load in a bridge-tied-load configuration.

Ain another aspect there is provided a driver circuit for driving a load comprising: a digital signal processor configured to receive an input signal and output a processor output signal based on the input signal; and a driver circuit having a forward signal path configured to receive the processor output signal and to generate a corresponding drive signal for driving the load. The digital signal processor is configured to implement an estimator to generate an estimate of a voltage of the drive signal based on the processor output signal, wherein the estimator is configured to not receive any feedback signal from the forward signal path of the driver circuit.

It should be noted that, unless expressly indicated to the contrary herein or otherwise clearly incompatible, then any feature described herein may be implemented in combination with any one or more other described features.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 illustrates one conventional example of a switching driver apparatus with output voltage monitoring;

FIG. 2 illustrates an example of a switching driver with output voltage monitoring according to an embodiment; and

FIG. 3 illustrates synthesising the output voltage during a clipping event.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

Embodiments of the disclosure relate to output voltage monitoring for driver circuits, in particular for switched mode amplifiers such as class-D amplifiers or the like.

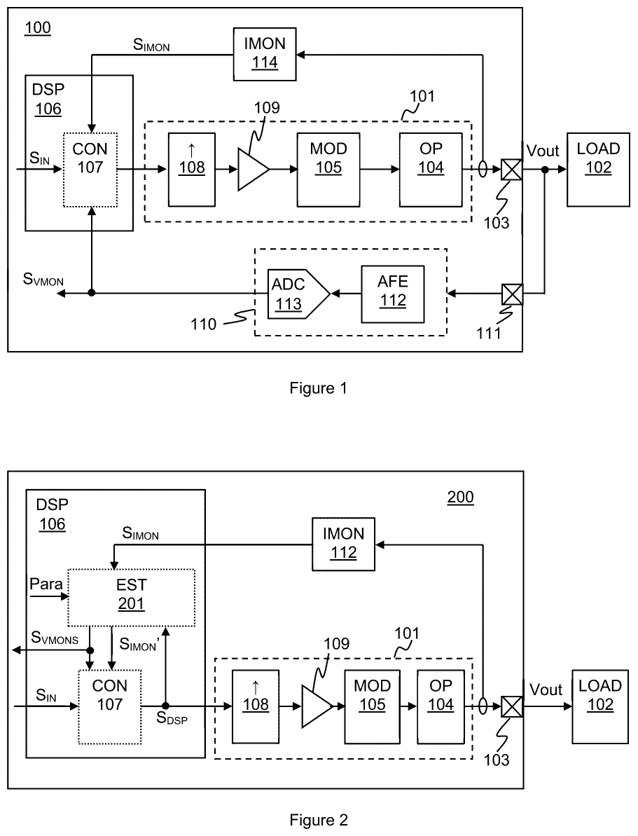

FIG. 1 illustrates one conventional example of a driver circuit 100 having a switching driver 101 for driving a transducer load 102 based on an input signal S_{IN}. In some applications the transducer load 102 could be an audio or acoustic output transducer, such as a loudspeaker of a host device of the driver apparatus or a speaker of an accessory device removably connected to the host device, or may be a haptic output 30 transducer, such as linear resonant actuator or the like. In general, a variety of different types of transducer may be driven by a suitable switching driver.

The driver circuit 100 may typically be implemented as an integrated circuit (IC), with the load 102 coupled to at least one output terminal 103 of the driver circuit via an external, i.e. off-chip, path. In some implementation, some output filtering (not illustrated) may be applied in the external path.

The switching driver 101 is configured to selectively switch the output terminal between different voltages, referred to herein as switching voltages, with a controlled duty cycle or modulation index, so as to generate a suitable output voltage Vout (on average over the course of one or more switching cycles) for driving the load 102 based on the input signal S_{IN}. The switching driver 101 comprises an output stage 104, which may generally comprise a network of switches that can be selectively switched between different switch states so as to couple the different switching voltages to the output terminal 103. In some applications, at least one of the switching voltages may, in at least one mode of operation, be a voltage which is generated by a voltage generator (not illustrated), e.g. a boosted voltage generated by an inductive or capacitive boost circuit. In some applications, the switching driver 101 may be selectively operable in different modes, in which at least one of the switching voltages used is different in the different modes, and may selectively operate in a selected mode to provide the output signal in a given output voltage range.

In some cases, the network of switches of the output stage 104 may simply comprise first and second switches for selectively connecting the output terminal 103 to either of two different switching voltages respectively, but other arrangements of switching driver, which may comprise a more complex network of switches for selectively switching the output terminal between selected switching voltages, may be implemented. A modulator 105 is configured to control switching of the output stage 104 between selected switch states with a controlled duty-cycle based on the input signal S_{IN}. The modulator 105 may typically be implemented as a closed-loop modulator and thus may receive a feedback signal (not illustrated in FIG. 1) indicative of the output from the switching driver 101. The modulator 105 may comprise a PWM modulator, e.g. a sigma-delta PWM modulator as would be understood by one skilled in the art.

The driver circuit 100 also comprises some processing circuitry, in this example a digital signal processor (DSP) 106, for processing of the input signal S_{IN} upstream of the switching driver 101. The DSP 106 may be configured to provide some signal conditioning 107 of the input signal Sin, for example to provide some protection of the transducer as will be described in more detail below.

In some applications the driver circuit may comprise some additional components for processing of the signal S_{DSP} which is output from the DSP 106, for example FIG. 1 illustrates that there may be an interpolator/upsampler 108 for increasing the sample rate of the signal and at least one digital gain element 109 in a digital path of switching driver 101. It will, of course, be understood the switching driver may also comprise additional components.

The driver circuit 100 of FIG. 1 also comprises some voltage monitoring circuitry 110 for monitoring the output voltage Vout to the load 102. In the example of FIG. 1, the output voltage Vout is monitored at a monitoring point near to the load 102, to monitor the actual voltage at the load and thus take account of any effect on the output voltage of at least part of the external path. The driver apparatus 100 may thus comprise a voltage monitor terminal 111 for receiving the voltage from the monitoring point. The voltage monitoring circuitry 110 comprises an analog front end (AFE) 112 for receiving the feedback voltage, which may be a relatively high voltage signal suitable for driving a transducer, followed by a suitable analog-to-digital converter (ADC) 113, which will generally be a relatively high-resolution ADC, for generating a signal S_{VMON} indicative of the output voltage. This signal S_{VMON} indicative of the output voltage may, be provided to the DSP 106 for processing as part of controlling operation of the driver apparatus 100 and/or for implementing some protection for the load, e.g. to prevent thermal overload or over-driving of the load 102. For instance, in some applications, the signal conditioning 107 of the DSP 106 may use the indication S_{VMON} of the output voltage together with an indication S_{IMON} of an output current from the switching driver to the load, which is monitored by current sensing block 114, to determine an indication of load resistance. Such an indication of load resistance may be useful for thermal protection of the load, as the load resistance for a loudspeaker or the like has a dependence on temperature. In some implementations, the DSP may be configured to output a signal to the switching driver 101 which includes a pilot tone component at a defined pilot tone frequency and to signal components at the defined pilot tone frequency in the S_{VMON} and S_{IMON} signals to determine the load resistance. The pilot tone component may generally be configured to be substantially unnoticeable in the load transducer output, e.g. in an audio implementation the pilot tone component may be configured to be inaudible in the transducer output.

The signal S_{VMON} may, in some cases, also be output to some other circuitry of the driver circuit 100 or some external processor/controller for additional or alternative monitoring and/or control.

Such an arrangement can satisfactorily monitor the output voltage Vout, but the circuit area required for the AFE 112 and ADC 113 of the voltage monitoring circuitry 110 may be relatively significant, which can add to the cost of the driver circuit 100.

It should be noted that FIG. 1 illustrates an embodiment in which the output voltage is measured near to the load and thus is monitored externally, i.e. off chip, to the driver circuit 100. In some implementations, the output voltage Vout could instead by monitored on-chip, i.e. within the driver circuit 100, which may avoid the need for the voltage monitor terminal 111, but generally there would still be a need for an AFE 112 and ADC 113.

It should also be noted that FIG. 1 illustrates just one output terminal 103. In some cases, the driver circuit 100 may be implemented in a single-ended driver configuration and the voltage at the output terminal 103 may be modulated between the relevant switching voltages with a controlled duty-cycle by the switching driver 101 to generate a suitable output voltage for driving the load 102, with the other side of the load being connected, in use, to a defined DC voltage that doesn't vary with the input signal, e.g. ground. Alternatively, the driver circuit 100 may be implemented in a bridge-tied-load (BTL) driver configuration, in which the load 102 will be connected between first and second output terminals of the driver circuit, each of which is modulated between selected switching voltages with respective duty-cycles based on the input signal so as to develop the desired drive voltage across the load. For a BTL configuration it may be desirable to monitor the output voltage across the load, and in that case the AFE 112 may be differential AFE.

Embodiments of the present disclosure relate to methods and apparatus for monitoring the output voltage of a driver which avoids the need for dedicated voltage monitoring hardware. In particular, the voltage monitoring may be performed upstream of the driver or amplifier by a suitable processor, e.g. by suitably configured firmware of the driver circuit.

FIG. 2 illustrates an example of a driver circuit 200 according to an embodiment, in which similar components to those discussed with reference to FIG. 1 are identified by the same reference labels.

The driver circuit 200 of the example of FIG. 2, which may be implemented as an integrated circuit, has a switching driver 101 which may comprise an output stage 104 driven by a modulator 105 in a similar manner as discussed with reference to FIG. 1.

The driver circuit 200 also comprises some processing circuitry, in this example a DSP 106, to provide some processing, e.g. signal conditioning 107, of the input signal S_{IN} upstream of the switching driver 101. As discussed with reference to FIG. 1, the output signal D_{DSP} from the DSP may be upsampled by interpolator 108 and subject to some digital gain applied by gain element 109 in a digital path of switching driver 101.

In the example of FIG. 2, the driver circuit 200 also comprises current sensing block 114 configured to monitor the output current from the switching driver 101 and provide a current signal S_{IMON} in a similar manner as discussed with reference to FIG. 1.

The driver circuit 200 does not, however, comprise dedicated hardware for monitoring the output voltage Vout of the switching driver 101. Instead, in the example of FIG. 2, an estimator 201 is implemented within the DSP 106 and the estimator 201 is configured to estimate or synthesise the output voltage Vout from the switching driver 101. The estimator 201 generates a synthesised voltage monitoring signal S_{VMONS} indicative of the estimated output voltage, which can then be used by the signal conditioning 107 of the DSP 106 for conditioning of the input signal Sin, e.g. to provide thermal and/or excursion protection for the transducer 102 and/or clipping prevention for the switching driver 101 and/or any other desired signal enhancement. The synthesised voltage monitoring signal S_{VMONS} may, in some implementations, also be output to some other circuitry of the driver circuit 100 or some external processor/controller for additional or alternative monitoring and/or control.

The estimator 201 is configured to estimate the output voltage Vout of the switching driver 101 based on the signal S_{DSP} output from the DSP 106 to the switching driver 101, which represents the input signal Sin after any signal conditioning 107 applied by the DSP 106. In at least some embodiments, the estimator 201 is configured to apply a first transfer function to the DSP output signal S_{DSP} to generate the synthesised voltage monitoring signal S_{VMONS}.

The first transfer function may comprise a transfer function which has been determined for the driver circuit 200 by testing and evaluation during circuit fabrication and/or by modelling. In particular, the first transfer function may be based on a transfer function determined as part of a system identification process during circuit fabrication. As will be understood by one skilled in the art, system identification is a process that may be performed as part of a testing and evaluation stage of integrated circuit fabrication and may involve operating at least part of the driver circuit 100 with defined stimuli.

In particular, the system identification may comprise the driver circuit 200 being operated to provide a drive signal to a known fixed resistance load. The output current, as monitored by the current sensing circuitry 114 can be determined and a transfer function between the DSP output S_{DSP} and the monitored current S_{IMON} may be determined.

In general, in normal operation of the switching driver 101, the waveform of the output voltage will generally match the waveform of the output current reasonably well (where the output voltage and current waveforms correspond to the average voltage or current over a switching cycle), with only a slight phase mismatch. As such, the transfer function between the DSP output signal S_{DSP} and the monitored current S_{IMON} is also generally also representative of the transfer function between the DSP output signal S_{DSP} and the output voltage Vout. The transfer function between the DSP output signal S_{DSP} and the monitored current S_{IMON} can thus be determined during system identification and used as the basis for the first transfer function.

In some implementations, the switching driver 101 may comprise a filter (not illustrated), for instance a high-pass filter with a relatively low cut-off frequency, and the presence of such a filter may cause complications for determining the transfer function between the DSP output signal S_{DSP} and the monitored current S_{IMON} during system identification. In such a case, it may be advantageous to disable the filter during system identification. However, as the filter will be active during normal operation, the effect of the filter should be included in the first transfer function used to estimate the synthesised voltage monitoring signal S_{VMONS}. The effect of the filter can be modelled and used to adapt the transfer function which was determined during system identification to provide the first transfer function which is used by the estimator 201.

It should be noted that the system identification will generally provide the required transfer function for the relevant design of driver circuit, but there could be some part-to-part variation for the transfer function for an individual circuit. However, for each circuit as implemented in an electronic device, there will generally be some transducer calibration performed and this transducer calibration can largely mitigate any error in the transfer function.

The first transfer function for the driver circuit 100 may thus be determined as part of a circuit fabrication process and the relevant transfer function may be stored for use by the estimator 201 of the DSP 106. In use, the estimator 201 receives the signal S_{DSP} which will be output from the DSP 106 and applies the first transfer function, e.g. filters the signal S_{DSP} using the first transfer function. The estimator 201 may also apply a delay to match the propagation delay through the switching driver 101 so as that the synthesised voltage monitoring signal S_{VMONS} has the correct timing for the actual voltage output and is matched in time with the current monitoring signal S_{IMON}.

It will be understood that as the synthesised voltage monitoring signal S_{VMONS} is generated based on the output signal from the DSP, i.e. the signal S_{DSP}, then any gain (amplification or attenuation) which applied in the downstream path, e.g. a digital gain applied by the gain element 109 and/or any analog gain applied the switching driver 101 should be taken into account. In at least some implementations, the estimator 201 may be configured to receive an indication, Para, of one or more parameters of the switching driver 101 which are indicative of the gain of the switching driver 101, for instance an indication of any digital or analog gain applied by the switching driver.

In addition, if the operation of the switching driver 101 becomes clipped, i.e. if the switching driver 101 is not able to fully reproduce the required output signal based on the input to the switching driver, then the synthesised voltage monitoring signal S_{VMONS} based S_{DSP} will be incorrect. The estimator 201 may thus be configured to determine whether the output of the switching driver 101 is, or is expected to be, in a clipped state and, if so, to vary the synthesised voltage monitoring signal S_{VMONS} accordingly.

In some implementations, the estimator 201 may compare the magnitude of the synthesised output voltage with a clipping threshold indicative of the maximum output voltage that can be produced by the switching driver 101. If the magnitude of the synthesised output voltage is lower than the clipping threshold, the estimator 201 may assume that the switching driver 101 is not operating in clipped state and the synthesised voltage monitoring signal S_{VMONS} can be used as a reasonable estimate of the output voltage Vout. However, if the magnitude of the synthesised output voltage would exceed the clipping threshold, then it may be assumed that the switching driver 101 is operating in clipped state. In this case, the value of the synthesised output voltage may be set to be equal to the value of the clipping threshold, as being indicative of the maximum voltage output of the switching driver. In other words, the synthesised voltage monitoring signal S_{VMONS} may be limited so as to not exceed the clipping threshold.

The parameters of the switching driver supplied to the estimator 201 may thus include parameters which allow the estimator to determine the relevant clipping threshold, which may, for instance, comprise an indication of at least one switching voltage used by the switching driver. For example, for a class-D switching driver where the output stage 104 switches an output node between a voltage VDRV and ground, the maximum output voltage, and hence the clipping level may be determined as:

$${V}_{DRV} * MI max * ( R load + R ext ) / ( R load + Rex t + R int ) \qquad Eqn . ( 1 )$$

where Mimax is the maximum modulation index that the switching driver may operate at, Rload is the resistance of the load, Rext is the resistance of the external path the load and Rint is the resistance of the internal path between the voltage supply and the output node.

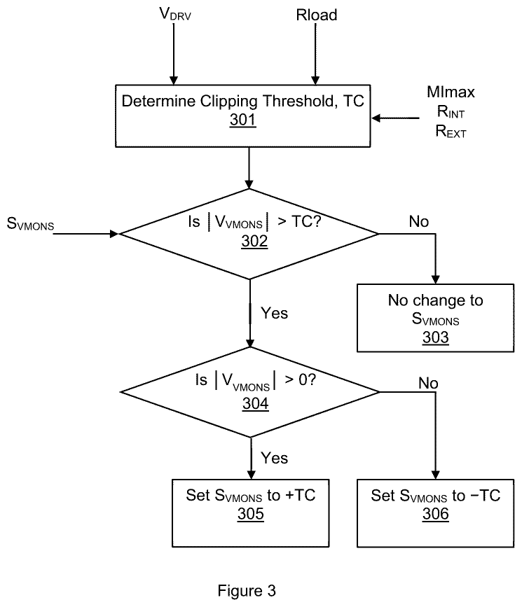

FIG. 3 illustrates one example of how the estimator 201 may apply limiting for clipping to the synthesised voltage monitoring signal S_{VMONS}. In block 301 the estimator 201 determines a clipping threshold TC for the switching driver based on the present operating conditions. For the example discussed in equation, the estimator may receive an indication of the relevant switching voltage VDRV and the load resistance Rload. The maximum modulation index MImax and internal path and external paths resistances Rint and Rext may be predetermined stored values.

In block 302 the estimator 201 compares the magnitude of S_{VMONS}, as determined by applying the first transfer signal to the DSP output signal S_{DSP}, and if S_{VMONS} is below the clipping threshold TC, then the present value of S_{VMONS} is maintained in block 303. If the magnitude of S_{VMONS} is below the clipping threshold TC, then the value of the S_{VMONS} may be limited. The example of FIG. 3 illustrates the process for a BTL switching driver, where each side of the load may be modulated between VDRV and ground and thus the output voltage may be positive or negative. At block 304 the estimator 203 thus determines whether the value of S_{VMONS} is positive, in which case the value of S_{VMONS} is set be a positive value equal to the clipping threshold i.e. +TC, or negative, in which case the value of S_{VMONS} is set be a negative value equal to the clipping threshold, i.e. −TC.

The synthesised voltage monitoring signal S_{VMONS} may be used for signal conditioning 107 by the DSP 106 in a similar manner as for a conventional voltage monitoring signal. For instance, the synthesised voltage monitoring signal S_{VMONS} may be used, together with the monitored current signal S_{IMON} as part of some protection function, to prevent over-driving of the transducer. For instance, the synthesised voltage monitoring signal S_{VMONS} may be used with the monitored current signal S_{IMON} to determine the resistance of the load transducer, for the purposes of thermal protection as would be understood by one skilled in the art. As noted above, the DSP 106 may be configured to add a signal component to the signal S_{DSP} at a defined pilot tone to aid in determining the load resistance.

In some implementations the synthesised voltage monitoring signal S_{VMONS} may also be used to calibrate the monitored current signal S_{IMON}. To account for possible variations in the current monitoring block it may be typical to calibrate the monitored current signal S_{IMON}. For a conventional driver circuit such as discussed with reference to FIG. 1, the voltage and current may be measured when driving the driver output high and low, with the load switchably disconnected. A suitable trim code may be determined based on the measured high and low current and load values and used to trim the monitored current signal S_{IMON}. In embodiments of the present disclosure the synthesised voltage monitoring signal S_{VMONS} can be used instead of the conventional measured voltage and a suitable trim code determined. In some implementations, the estimator 201 may thus calibrate the monitored current signal S_{IMON} based on the synthesised voltage monitoring signal S_{VMONS}, to provide a calibrated monitored current signal S_{IMON}′.

In some implementations, an adjustment may also be made to the monitored current signal S_{IMON} to account for temperature variations that can impact the value of the sensed current. In the conventional approach as illustrated in FIG. 1, each of S_{IMON} and S_{VMON} is generated by a respective ADC, and the ADCs are typically designed and laid out so as to exhibit similar PVT (process-voltage-temperature) characteristics, e.g. to have similar temperature coefficients. Any gain variation in the ADC of the current sensing circuitry 114 is thus typically the same as the gain variation for the ADC 113 of the voltage monitoring circuitry and these gain variations thus cancel for the value S_{IMON}/S_{VMON}. In embodiments of the present disclosure the synthesised voltage monitoring signal S_{VMONS} is generated based on the DSP output signal S_{DSP} and thus does not any variation with temperature. The parameters Para received by the estimator 201 may thus include an indication of the die temperature of the circuit and an appropriate correction can be applied to the monitored current signal S_{IMON} to compensate for temperature variations. The compensation may, for instance, comprise a first or second order polynomial correction function.

Embodiments of the present disclosure thus provide monitoring of the output voltage of a driver or amplifier, in particular a switched mode driver or amplifier such as a class-D amplifier or the like, where the output voltage is synthesised, e.g. by firmware running on a DSP or other processor of the driver circuit. Embodiments thus do not require a dedicated AFE and/or ADC for monitoring the output voltage. The omission of the conventional AFE and ADC for voltage monitoring provides significant savings in terms of circuit area, and hence cost, and also some saving in power consumption of the driver circuit. As the output voltage is synthesised based on the DSP output signal, there is no need to stream any data from the hardware of the switching driver to the firmware within the DSP for the output voltage. The output voltage is synthesised from the DSP output signal S_{DSP} before any interpolation/upsampling applied for the switching driver and the processing to synthesise the output voltage can thus be performed at the sample rate of the input signal Sin, e.g. at a conventional digital audio sample rate for audio applications, rather than the faster sample rate of the signal supplied to the modulator of the switching driver.

The synthesised output voltage signal can be generated with a small magnitude and phase error compared to the output voltage it is desired to monitor. Indeed, given the hardware limitation of monitoring the actual output voltage, the error in the synthesised voltage signal can, in some cases, be lower than the conventional hardware solutions, which can improve the reliability of the use of the monitored voltage, e.g. for transducer protection.

The examples above have been discussed in the context of the DSP 106 which implements the estimator being part of the same physical circuit as the switching driver 101, and thus implemented as an integrated circuit including the modulator 105 and the output stage 104. In some examples, however, the modulator 106 and output stage could be implemented separately, i.e. as separate integrated circuits or on separate chips. The modulator 105 may thus be formed as part of a drive circuit for generating one or more control signals for controlling switching of the separate output or power stage. The modulator may be implemented as part of a first integrated circuit with DSP which implements an estimator in a similar manner as discussed above. However, the output stage may be implemented as a separate output stage. Such an arrangement may be beneficial, in some cases, in allowing separate optimization of the drive circuit and the output stage.

The examples above have been discussed in the context of driving a transducer, which may in particular be an audio transducer, and embodiments of the present disclosure may advantageously be used in audio application or other applications for driving a transducer, e.g. such as haptic output transducer. However, the voltage monitoring may be applied to any application in which a switching driver is used to output an output voltage to a load based on an input signal.

The examples have been illustrated with just on output to the load being modulated, i.e. in a single ended driver configuration, but it will be understood that the driver apparatus may be implemented to drive a load in a BTL configuration and in this case voltage monitoring may be implemented for the differential voltage across the load.

Embodiments may be implemented in a host device, especially a portable and/or battery powered host device such as a mobile computing device for example a laptop, notebook or tablet computer, or a mobile communication device such as a mobile telephone, for example a smartphone. The device could be a wearable device such as a smartwatch.

The host device could be a games console, a remote-control device, a home automation controller or a domestic appliance, a toy, a machine such as a robot, an audio player, a video player. It will be understood that embodiments may be implemented as part of a system provided in a home appliance or in a vehicle or interactive display. There is further provided a host device incorporating the above-described embodiments.

The skilled person will recognise that some aspects of the above-described apparatus and methods, for instance the estimation of the output voltage, may be embodied as processor control code, for example on a non-volatile carrier medium such as a disk, CD- or DVD-ROM, programmed memory such as read only memory (Firmware), or on a data carrier such as an optical or electrical signal carrier. For some applications, embodiments may be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

As used herein, when two or more elements are referred to as “coupled” to one another, such term indicates that such two or more elements are in electrical, mechanical, or electromechanical communication, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

1. A driver circuit for driving a load comprising:
a digital signal processor configured to receive an input signal and output a processor output signal based on the input signal; and
a switching driver configured to receive the processor output signal and to generate a corresponding drive signal for driving the load;
where the signal processor is configured to implement an estimator to generate an estimate of a voltage of the drive signal based on the processor output signal.

2. The driver circuit of claim 1 wherein the switching driver comprises an upsampler to provide upsampling of the processor output signal and the estimator is configured to generate the estimate of the voltage of the drive signal based on the processor output signal.

3. The driver circuit of claim 1 wherein the estimator is configured to generate the estimate of the voltage of the drive signal by applying a first transfer function to the processor output signal.

4. The driver circuit of claim 3 wherein the first transfer function is a stored transfer function determined as part of a system identification process for the driver circuit.

5. The driver circuit of claim 3 wherein the estimator is configured to receive an indication of any gain applied by the switching driver and to scale the estimate of the voltage of the drive signal generated applying the first transfer function to the processor output signal so as to account for said gain.

6. The driver circuit of claim 1 wherein the estimator is configured to limit to maximum magnitude of the estimate of the voltage of the drive signal to a clipping threshold indicative of a maximum voltage magnitude of the driver signal that can be output from the switching driver.

7. The driver circuit of claim 6 wherein the estimator is configured to receive an indication of at least one parameter of operation of the switching driver and is configured to determine the clipping threshold.

8. The driver circuit of claim 7 wherein said indication of at least one parameter of operation of the switching driver comprises an indication of a switching voltage of the switching driver and a resistance of the load.

9. The driver circuit of claim 1 further comprising current sensing circuitry configured to monitor an output current of the switching driver and generate a current sense signal.

10. The driver circuit of claim 9 wherein the digital signal processor is configured to apply signal conditioning to the input signal to generate the processor output signal, wherein said signal conditioning uses the estimate of the voltage of the drive signal and the current sense signal to apply protection to prevent thermal overload of the load.

11. The driver circuit of claim 10 wherein the digital signal processor is configured to use the estimate of the voltage of the drive signal and the current sense signal to generate a value indicative of load resistance.

12. The driver circuit of claim 10 wherein the estimator is configured to receive an indication of a die temperature of the driver circuit and is configured to apply a temperature dependent compensation to at least one of the estimate of the voltage of the drive signal and the current sense signal before generating the value indicative of load resistance.

13. The driver circuit of claim 9 wherein the estimator is configured to apply calibration to the current sense signal based on the estimate of the voltage of the drive signal.

14. The driver circuit of claim 1 wherein the driver circuit is an audio driver circuit configured to drive an audio output transducer.

15. The driver circuit of claim 1 wherein the driver circuit is configured to drive the load in a bridge-tied-load configuration.

16. A driver circuit for driving a load comprising:
a digital signal processor configured to receive an input signal and output a processor output signal based on the input signal; and
a driver circuit having a forward signal path configured to receive the processor output signal and to generate a corresponding drive signal for driving the load;
where the digital signal processor is configured to implement an estimator to generate an estimate of a voltage of the drive signal based on the processor output signal, wherein the estimator is configured to not receive any feedback signal from the forward signal path of the driver circuit.
